(19) United States
(12) Patent Application Publication
(10) Pub. No.: US 2013/0241310 A1
(43) Pub. Date: Sep. 19, 2013

(54) Hall effect transformer

(71) Applicant: Chao-Cheng Lu, Taipei (TW)

(72) Inventor: Chao-Cheng Lu, Taipei (TW)

(21) Appl. No.: 13/385,935

(22) Filed: Mar. 16, 2012

(51) Int. Cl. H02M 5/08; H01L 43/06

(52) U.S. Cl. 307/109; 257/295; 257/E43.003

(57) ABSTRACT

This invention relates is a Hall effect transformer, which include: Hall effect device, insulation layer and semiconductor, place the insulator layer between the Hall effect device and semiconductor used as an isolated, when AC current flow through the AC capacitors and Hall effect device, semiconductor corresponds to get both terminals of the AC voltage, and AC power transmission purposes.

### BACKGROUND OF THE INVENTION

1. Field of the Invention

The present invention related to Hall effect transformer, application Hall effect principle, in Hall effect device and semiconductor of middle place has insulated layer do for isolation of uses, when AC current flows through AC capacitor and Hall effect device, in semiconductor terminals are relative should of AC voltage, because Hall effect device and semiconductor of middle place has insulated layer to do for isolated of with, and can reached has isolation and the AC power transfer of function.

2. Description of Related Art

Learning about the charge carriers of a current carrying conductor placed in a transverse magnetic field experience a sideways Lorentz force: This results in a charge separation in a direction perpendicular to the current and to the magnetic field. The resultant voltage in that direction is proportional to the applied magnetic field. This is known as the Hall effect. U.S. Pat. No. 4,398,342 and U.S. Pat. No. 6,108,185 known, its electric field EF, current I, and magnetic field B relationship for right hand rule by specification, its Hall voltage VH=IB/nde, formula in the I is the current flows through the device, B is the applied magnetic field intensity, n is the carrier concentration of the device material, e is the electronic charge and d is the device thickness. Since formula in the known, Hall voltage VH and current I and magnetic field intensity B into is proportional to the cases, when current I and magnetic field B is large, the Hall voltage VH is higher, is also positive charge and negative charge more about focus the device two terminals.

Patents from the above expositive and in modern semiconductor products and not found the following points:
1. Application is not found to be equipped with insulating layer and Semiconductor device in Hall effect devices, generation at two terminals of the Hall voltage of the semiconductor device.
2. Has not found any AC (Alternating Current, AC) power source and AC capacity connected in series with Hall effect device, as Hall effect transformer power supply, and has the traditional transformer isolation and AC power transmission function.

### SUMMARY OF THE INVENTION

In order to provide the Hall effect transformer:

The first object of the present invention for the use of the Hall effect transformer reached short, thin, light, AC power and DC power transmission function.

The second object of the present invention for the use of the Hall effect transformer reached isolation characteristics of transmission of AC power and DC power purposes.

### BRIEF DESCRIPTION OF THE DRAWINGS

FIG. 1 is a structural diagram of a first embodiment of the present invention.

FIG. 2 is a structural diagram of a second embodiment of the present invention.

FIG. 3 is a circuit diagram of a first embodiment of the present invention.

FIG. 4 is a circuit diagram of a second embodiment of the present invention.

### DETAILED DESCRIPTION OF THE PREFERRED EMBODIMENTS

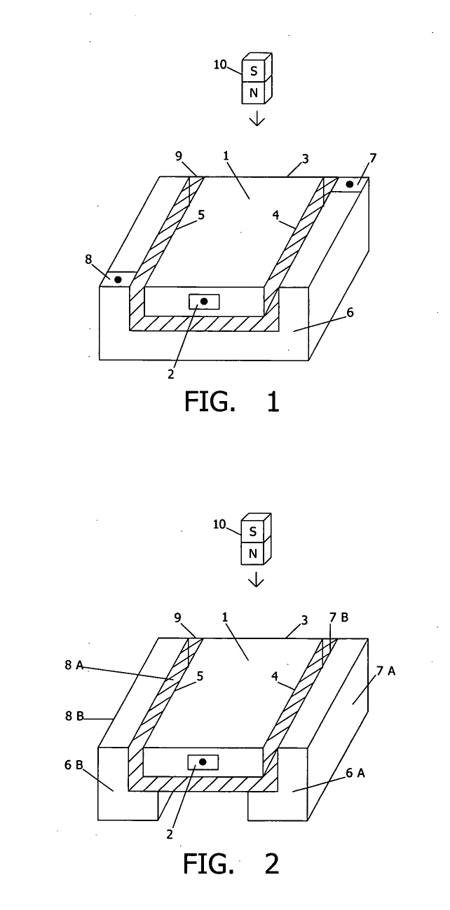

As shown in FIG. 1 is a structural diagram of a first embodiment of the present invention. In FIG. 1, Hall effect device comprises permanent magnetic 10 and Hall effect semiconductor 1, permanent magnetic 10 of north pole N direction for diagram of direction, Hall effect semiconductor 1 front terminal is first current terminal 2, back terminal is second current terminal 3, right terminal of Hall effect semiconductor 1 is first Hall voltage 4, left terminal of Hall effect semiconductor 1 is second Hall voltage 5, right terminal of semiconductor 6 is first voltage terminal 7, left terminal of semiconductor 6 is second voltage terminal 8, the insulator layer 9 were set in between Hall effect semiconductor 1 and semiconductor 6, for Hall effect semiconductor 1 and semiconductor 6 insulated, insulator layer 9 usually to metal oxidation semiconductor or other insulator material by made; This invention of the Hall effect semiconductor 1 and semiconductor 6 for N-type semiconductor, P-type semiconductor or conductor defined according to need, without limit.

As shown in FIG. 1, the operation principle is: First set Hall effect semiconductor 1 and semiconductor 6 of middle placed has insulator layer 9 constitute capacitor feature, when first Hall voltage terminal 4 of Hall effect semiconductor 1 has large of positive voltage, at this time insulator layer 9 considered capacitor of dielectric, due to first Hall voltage terminal 4 has large of positive voltage, so produced large of electric field in the insulator layer 9 capacitor corresponding of semiconductor 6, in first Hall voltage terminal 4 produced positive charge, and in semiconductor 6 surface rendering negative charge; when Hall effect semiconductor 1 of second Hall voltage terminal 5 has large of negative voltage, at this time insulator layer 9 considered capacitor of dielectric, due to second Hall voltage terminal 5 has large of negative voltage, so produced large of electric field in insulator layer 9 capacitor corresponding of semiconductor 6, in second Hall voltage terminal 5 produced negative charge, and in semiconductor 6 surface rendering positive charge; by above theory analysis known, through first Hall voltage terminal 4 and second Hall voltage terminal 5 of Hall effect semiconductor 1 are positive charge and negative charge alternate changes, first voltage terminal 7 and second voltage terminal 8 of semiconductor 6 corresponds to the negative-positive charge alternate changes, and achieve the purpose of this invention can transmit power.

As shown in FIG. 2 is a structural diagram of a second embodiment of the present invention. In FIG. 2, Hall effect device comprises permanent magnetic 10 and Hall effect semiconductor 1, permanent magnetic 10 of north pole N direction for diagram of direction, Hall effect semiconductor 1 front terminal is first current terminal 2, back terminal is second current terminal 3, right terminal of Hall effect semiconductor 1 is first Hall voltage 4, left terminal of Hall effect semiconductor 1 is second Hall voltage 5, right terminal of semiconductor 6A is right voltage terminal 7A, left terminal of semiconductor 6A is left voltage terminal 7B, right terminal of semiconductor 6B is right voltage terminal 8A, left terminal of semiconductor 6B is left voltage terminal 8B, the insulator layer 9 were set in between Hall effect semiconductor 1, semiconductor 6A, and semiconductor 6B, for Hall effect semiconductor 1, semiconductor 6A, and semiconductor 6B insulated, insulator layer 9 usually to metal oxidation semiconductor or other insulator material by made; This invention of the Hall effect semiconductor 1 and semiconductor 6 for N-type semiconductor, P-type semiconductor or conductor defined according to need, without limit.

As shown in FIG. 2, the operation principle is: First set Hall effect semiconductor 1 and semiconductor 6 of middle placed has insulator layer 9 constitute capacitor feature, when first Hall voltage terminal 4 of Hall effect semiconductor 1 has large of positive voltage, at this time insulator layer 9 considered capacitor of dielectric, due to first Hall voltage terminal 4 has large of positive voltage, so produced large of electric field in the insulator layer 9 capacitor corresponding of first semiconductor 6A, in first Hall voltage terminal 4 produced positive charge, and in first semiconductor 6A surface rendering negative charge 7B, and surface rendering positive charge 7A; when Hall effect semiconductor 1 of second Hall voltage terminal 5 has large of negative voltage, at this time insulator layer 9 considered capacitor of dielectric, due to second Hall voltage terminal 5 has large of negative voltage, so produced large of electric field in insulator layer 9 capacitor corresponding of second semiconductor 6B, in second Hall voltage terminal 5 produced negative charge, and in semiconductor 6B surface rendering positive charge 8A, and surface rendering negative charge 8B; by above theory analysis known, through first Hall voltage terminal 4 and second Hall voltage terminal 5 of Hall effect semiconductor 1 are positive charge and negative charge alternate changes, first voltage terminal 7A of first semiconductor 6A and second voltage terminal 8B of second semiconductor 6B corresponds to the positive charge and negative charge alternate changes, and achieve the purpose of this invention can transmit power.

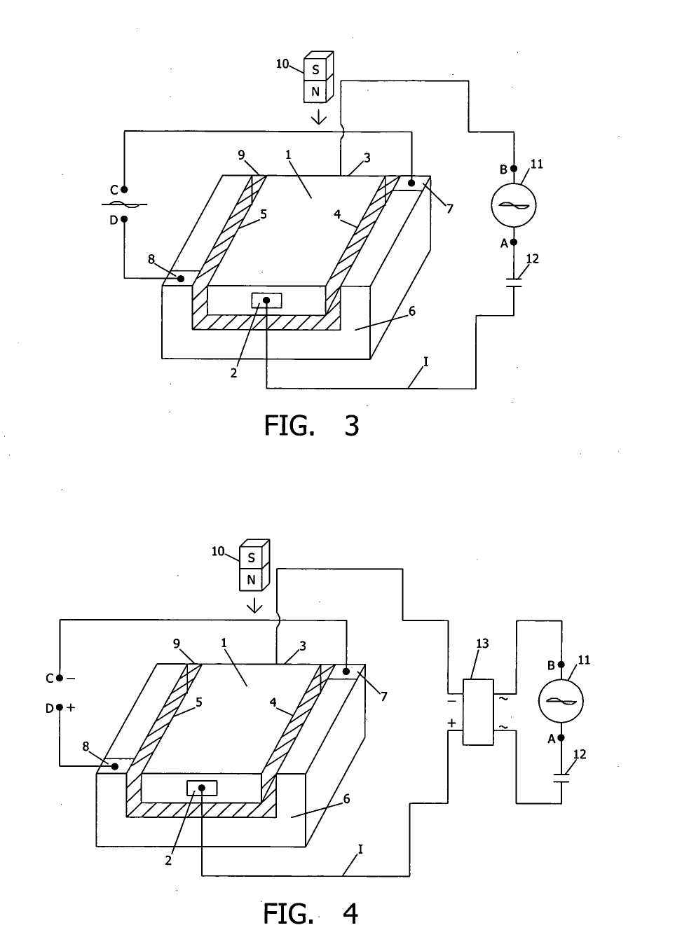

As shows in FIG. 3, is a circuit diagram of a first embodiment of the present invention. In FIG. 3, while the AC power source connected to AC power terminal 11, first terminal A of AC power terminal 11 connected to second terminal of AC capacity 12, first terminal of AC capacity 12 connected to first current terminal 2 of Hall effect semiconductor 1, second terminal B of AC power terminal 11 connected to second current terminal 3 of Hall effect semiconductor 1, first voltage terminal 7 of semiconductor 6 connected to first voltage output terminal C, second voltage terminal 8 of semiconductor 6 connected to second voltage output terminal D.

As shows in FIG. 3, when the voltage at first terminal A of AC power terminal 11 is positive, terminal B is negative, the path of the current I flow is from first terminal A of the AC power terminal 11 though AC capacity 12, first current terminal 2 of Hall effect semiconductor 1, second current terminal 3 of Hall effect semiconductor 1, and back to second terminal B of AC power terminal 11, the Hall voltage of first Hall voltage terminal 4 of Hall effect semiconductor 1 is positive, positive electric field induction the positive voltage of first voltage terminal 7 of semiconductor 6, makes first voltage terminal 7 of semiconductor 6 for negative charge terminal, also is negative voltage terminal.

As shows in FIG. 3, when the voltage at second terminal B of AC power terminal 11 is positive, terminal A is negative, the path of the current I flow is from second terminal B of the AC power terminal 11 though second current terminal 3 of Hall effect semiconductor 1, first current terminal 2 of Hall effect semiconductor 1, AC capacity 12, and back to first terminal A of AC power terminal 11, the Hall voltage of first Hall voltage terminal 5 of Hall effect semiconductor 1 is positive, positive electric field induction the positive voltage of second voltage terminal 8 of semiconductor 6, makes second voltage terminal 8 of semiconductor 6 for negative charge terminal, also is negative voltage terminal.

As shows in FIG. 4, is a circuit diagram of a second embodiment of the present invention. In FIG. 4, while the AC power source connected to AC power terminal 11, first terminal A of AC power terminal 11 connected to second terminal of AC capacity 12, first terminal of AC capacity 12 connected to first AC terminal of full-wave rectifier 13, second AC terminal of full-wave rectifier 13 connected to second terminal B of AC power terminal 11, positive voltage terminal of full-wave rectifier 13 connected to first current terminal 2 of Hall effect semiconductor 1, negative voltage terminal of full-wave rectifier 13 connected to second current terminal 3, first voltage terminal 7 of semiconductor 6 connected to first voltage output terminal C, second voltage terminal 8 of semiconductor 6 connected to second voltage output terminal D.

As shows in FIG. 4, when the voltage at first terminal A of AC power terminal 11 is positive, terminal B is negative, the path of the AC current flow is from first terminal A of AC power terminal 11 though AC capacity 12, first AC terminal of full-wave rectifier 13, second AC terminal of full-wave rectifier 13, and back to second terminal B of AC power terminal 11, the path of the current I flow is from positive voltage terminal of the full-wave rectifier 13 though first current terminal 2 of Hall effect semiconductor 1, second current terminal 3 of Hall effect semiconductor 1, and back to negative voltage terminal of full-wave rectifier 13, the Hall voltage of first Hall voltage terminal 4 of Hall effect semiconductor 1 is positive, positive electric field induction the positive voltage of first voltage terminal 7 of semiconductor 6, makes first voltage terminal 7 of semiconductor 6 for negative charge terminal, also is negative voltage terminal; the Hall voltage of second Hall voltage terminal 5 of Hall effect semiconductor 1 is negative, negative electric field induction the negative voltage of second voltage terminal 8 of semiconductor 6, makes second voltage terminal 8 of semiconductor 6 for positive charge terminal, also is positive voltage terminal.

As shows in FIG. 4, when the voltage at second terminal B of AC power terminal 11 is positive, first terminal A is negative, the path of the AC current flow is from second terminal B of AC power terminal 11 though second AC terminal of full-wave rectifier 13, first AC terminal of full-wave rectifier 13, AC capacity 12, and back to first terminal A of AC power terminal 11, the path of the current I flow is from positive voltage terminal of the full-wave rectifier 13 though first current terminal 2 of Hall effect semiconductor 1, second current terminal 3 of Hall effect semiconductor 1, and back to negative voltage terminal of full-wave rectifier 13, the Hall voltage of first Hall voltage terminal 4 of Hall effect semiconductor 1 is positive, positive electric field induction the positive voltage of first voltage terminal 7 of semiconductor 6, makes first voltage terminal 7 of semiconductor 6 for negative charge terminal, also is negative voltage terminal, the Hall voltage of second Hall voltage terminal 5 of Hall effect semiconductor 1 is negative, negative electric field induction the positive voltage of second voltage terminal 8 of semiconductor 6, makes second voltage terminal 8 of semiconductor 6 for positive charge terminal, also is positive voltage terminal

As shows FIG. 4, since above of action principle known, first current terminal 2 of Hall effect semiconductor 1 can connected to positive voltage terminal or negative voltage terminal, and second current terminal 3 of Hall effect semiconductor 1 can connected to negative voltage terminal or positive voltage terminal, also that is to positive voltage terminal and negative voltage terminal of full-wave rectifier 13, so this invention may also application for DC power transfer.

What is claimed is:

1. A Hall effect transformer comprising:
a Hall-effect device, placed above the insulator layer;
an insulator layer, placed in the middle of Hall effect device and semiconductor; and
a semiconductor.

2. A Hall effect transformer as in claim 1, wherein said Hall effect device having a first current terminal and a second current terminal.

3. A Hall effect transformer as in claim 1, wherein said insulator layer is a metal oxidation semiconductor or a insulator material.

4. A Hall effect transformer as in claim 1, wherein said semiconductor includes a first voltage terminal and a second voltage terminal.

5. A Hall effect transformer as in claim 1, wherein said semiconductor includes one or two semiconductor placed under the first voltage terminal and second voltage terminal of Hall effect device.

6. A Hall effect transformer as in claim 1, wherein said semiconductor includes N-type semiconductor, P-type semiconductor or conductor.

7. A power transfer circuits comprising:
a AC power terminal, Provides connected to AC power source;
a AC capacity, connected in series with the AC power terminal and Hall effect transformer; and
a Hall effect transformer, can be achieved isolation and the AC power transmission function.

8. A power transfer circuits as in claim 7, wherein said Hall effect transformer includes a first current terminal, a second current terminal, a first voltage terminal and a second voltage terminal.

9. A power transfer circuits as in claim 7, wherein said AC power terminal includes a first terminal and a second terminal.

10. A power transfer circuits as in claim 7, wherein said AC capacity includes a first terminal and a second terminal.

11. A power transfer circuits as in claim 8, wherein said first current terminal of Hall effect transformer connected to the first terminal of AC capacitor.

12. A power transfer circuits as in claim 8, wherein said second current terminal of Hall effect transformer connected to the second terminal of AC power terminal.

13. A power transfer circuits as in claim 9, wherein said first terminal of AC power terminal connected to the second terminal of AC capacity.

14. A power transfer circuits as in claim 10, wherein said first terminal of AC capacity connected to the first AC terminal of full-wave rectifier.

15. A power transfer circuits as in claim 8, wherein said first current terminal of Hall effect transformer connected to positive voltage terminal or negative voltage terminal of full-wave rectifier.

16. A power transfer circuits as in claim 8, wherein said second current terminal of Hall effect transformer connected to negative voltage terminal or positive voltage terminal of full-wave rectifier.

17. A power transfer circuits as in claim 9, wherein said second terminal of AC power terminal connected to second AC terminal of full-wave rectifier.

18. A power transfer circuits as in claim 8, wherein said first current terminal of Hall effect transformer connected to positive terminal or negative terminal of DC power source.

19. A power transfer circuits as in claim 8, wherein said second current terminal of Hall effect transformer connected to positive terminal or negative terminal of DC power source.
